(19) United States
(12) Patent Application Publication
(10) Pub. No.: US 2002/0111757 A1
(43) Pub. Date: Aug. 15, 2002

(54) Diagnostic device with mouse-controlled switching among display control functions

(76) Inventors: Bert Boehler, Schwabach (DE); Jean-Marie Clement, Erlangen (DE); Petra Tamara Giesen, Oberasbach (DE); Marc Rose, Erlangen (DE)

Correspondence Address: SCHIFF HARDIN & WAITE, 6600 SEARS TOWER, 233 S WACKER DR, CHICAGO, IL, 60606-6473, US

(21) Appl. No.: 10/038,167

(22) Filed: Oct. 23, 2001

(30) Foreign Application Priority Data
Oct. 23, 2000 (DE) 10052535.0

(51) Int. Cl. G01R 19/00

(52) U.S. Cl. 702/64

(57) ABSTRACT

A diagnostic device has a modality for generating raw data, a computer (8) for calculating image data from the raw data, an imaging system for converting the image data into image signals, an input device with a mouse and a display unit. The imaging system allows representations of the images on the display unit to be influenced by control functions by means of the mouse. The input device has a detector which detects a movement of the mouse one of a number of predetermined directions and effects a switching or change of one control function to another in order to vary the representation of the images.

### BACKGROUND OF THE INVENTION

1. Field of the Invention

The present invention relates to a diagnostic device of the type having a modality for generating raw data, a computer for calculating image data from the raw data, an imaging system which converts the image data into image signals, an input device with a mouse, and a display unit, wherein the imaging system allows representations of the images on the display unit to be influenced by control functions by means of the mouse.

2. Description of the Prior Art

Three-dimensional (3D) volumetric data records in medical technology increasingly are being generated and visualized in computed tomography (CT) and magnetic resonance tomography (MR) and angiography examinations such as CTA or MRA.

In such displayed 3D visualizations, the so-called clip plane can be rotated and displaced, and the object itself can be rotated or zoomed inside the volume, in particular the volume of a human body. The selection of these functions is undertaken, for example by actuating a particular keyboard key together with actuation of the control, shift and/or Alt key.

In recent software platforms, icons are provided on task cards and allow selection of the desired mode for setting by means of the mouse.

Such operations are, however, complicated and can only be achieved only when the person viewing the displayed 3D object shifts his or her field of view from the object so that the control function can be reliably executed.

### SUMMARY OF THE INVENTION

An object of the present invention is to provide a diagnostic device of the type described above wherein of the control functions can be undertaken when visualizing 2D and 3D images.

The object is achieved in accordance with the invention in a diagnostic device of the initially described type wherein the input device has a detector which detects a movement of the mouse in one of a number of predetermined directions and effects a switching or selection from one control function to another in order to vary the representation of the images. This is based on the recognition according to the invention that a movement in a prescribed direction, termed a gesture selection, can effect a changeover in the mode of the mouse. The changeover can then, for example, indicate on the display in a known way which mode is activated by marking a corresponding icon.

In the case of a diagnostic device having a modality for generating raw data of a volume, a computer for calculating three-dimensional images from the raw data, and the imaging system which is designed in such a way that representations of the 3D images on the reproduction apparatus can be influenced by control functions by means of the mouse, it has proved to be advantageous for the detector to effect a changeover of the control functions for the purpose of varying the three-dimensional representation of the 3D images, doing so on the basis of movements of the mouse.

According to the invention, the detector can effect an automatic changeover of the control functions by a brief actuation of the mouse in one of defined directions, the mouse being able to detect four defined directions as control functions by gesture selection.

The four defined directions can be oriented at respective 45° angles with respect to the vertical. However, according to the invention, it is also possible to use directions along the coordinate axes. If more control functions are to be switched, it is also possible, for example, to use eight directions for this purpose.

Instead of the four control functions, it is also possible, for example, to control eight functions by a combination of the two aforementioned crosses.

The imaging system can be designed so that by right-clicking the mouse a context menu is inserted in the display which symbolizes the directions of movement for the automatic changeover, controlled by the gesture selection, of the control functions, and provides explanations, so that skilled operators can learn the expert mode with the gesture selection. Long clicking with the mouse effects the insertion of a text menu according to the invention which symbolizes the directions of movement and effects the automatic changeover controlled by gesture selection. The appropriate advisory texts of the text menu are arranged at crossed double arrows which intersect the horizontal below 45° or are arranged in accordance with a coordinate cross.

In a further embodiment, the imaging system further supports the gesture selection by causing a classic text menu with the control functions to be displayed by briefly right-clicking with the mouse, such that even unskilled operators can use the control functions.

According to the invention, the control functions for varying the three-dimensional representation of the images can be rotation and displacement of the clip plane and rotation and zooming of the object.

### DESCRIPTION OF THE DRAWINGS

FIG. 1 shows the schematic design of a computed tomography apparatus constructed and operating in accordance with the invention.

FIG. 2 shows a rotated 3D object for explaining the invention.

FIG. 3 shows a 3D object with a first context menu in accordance with the invention.

FIG. 4 shows a 3D object with a second context menu in accordance with the invention.

FIG. 5 shows a further design of the first context menu in accordance with the invention.

### DESCRIPTION OF THE PREFERRED EMBODIMENTS

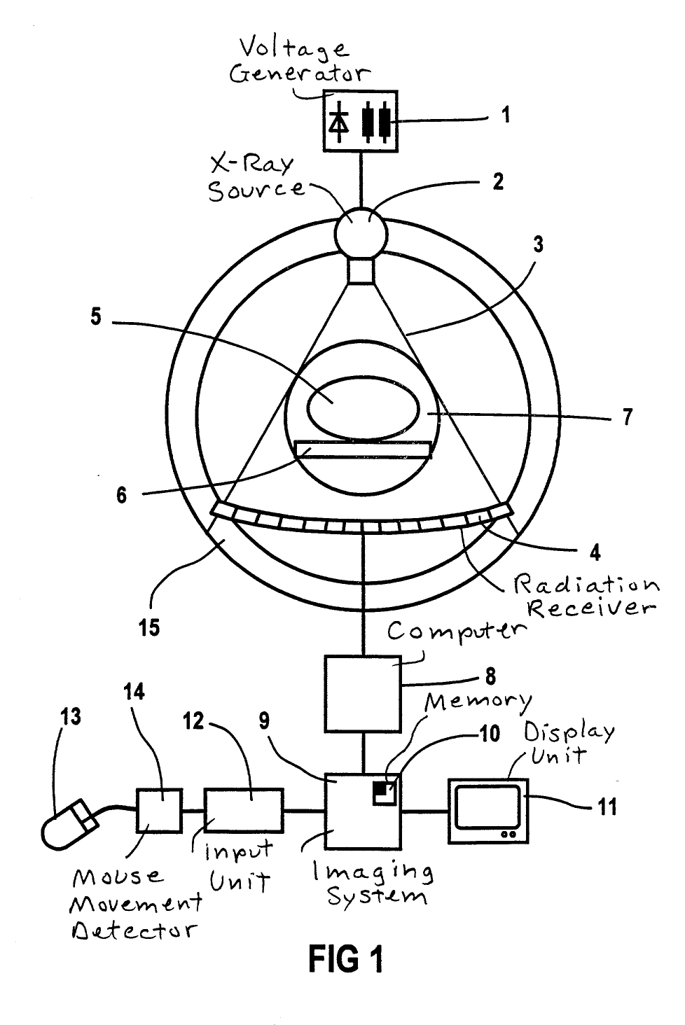

The computed tomography apparatus in FIG. 1 has, has, as a modality for generating three-dimensional medical images, a measuring unit composed of an X-ray source 2, which is fed by a volume generator 1 and emits a fan-shaped first X-ray beam 3, and a radiation receiver 4 which is composed of a series of individual detectors, for example of 512 individual detectors. The patient 5 to be examined lies on a patient positioning table 6. In order to scan the patient 5, the measuring unit 2, 4 is rotated by 360° around a measuring field 7 in which the patient 5 lies.

In this process, the voltage generator 1 is controlled to operate the X-ray source 1 in a pulsed fashion or with continuous radiation. At predetermined angular positions of the measuring unit, sets of data are generated which are fed by the radiation receiver 4 to a computer 8 which uses the generated data records to calculate the attenuation coefficients of predetermined pixels. Connected to the computer 8 is an imaging system 9 which can have a transducer, memory 10 and processing circuits for transforming the data from the computer 8 into image signals. The image system 9 is connected to a monitor 11 for reproducing the images of the radiographed slices of the patient 5. Also, connected to the imaging system 9 is an input device 12 which has a keyboard and a mouse 13.

The change in the direction of the useful radiation beam 3 is performed by rotating a gantry 15, with the aid of a rotary device (not illustrated), on which the X-ray source 2 and the radiation receiver 4 are mounted.

By a constructing a number of slices the spiral mode, this computed tomography apparatus can generate 3D volumetric data records which can be further processed by volume rendering in the imaging system 9 for the purpose of better visualization.

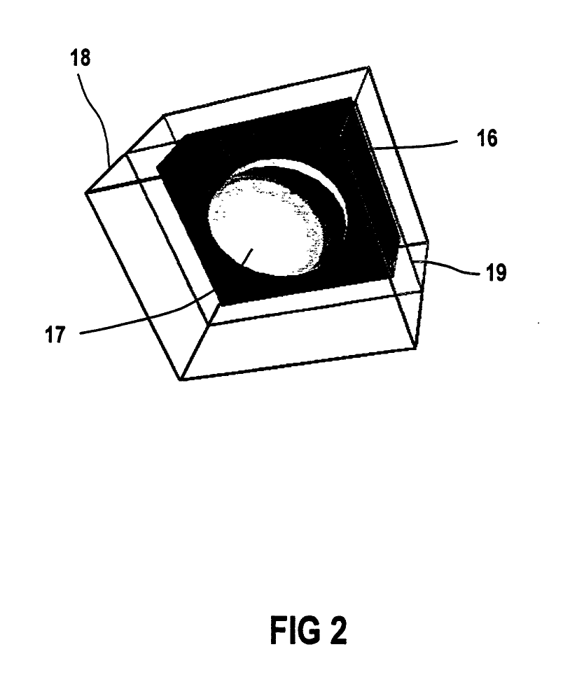

A simple 3D object is illustrated as an example in FIG. 2. This object is a hollow cube 16 in which a hollow sphere 17 is located. The two are surrounded by an envelope 18, termed a boundary box. The boundary surface, termed the clip plane 19, specifies the surface on which the observer views the 3D objects. The clip plane 19 has been given this designation due to its effect of cropping parts of the volumetric data record that are of no interest. The three-dimensional manner of viewing is illustrated by rotating the object with respect to the following figures. The empty hemisphere is intended to be seen in the hollow half cube, both being cropped by the clip plane 19.

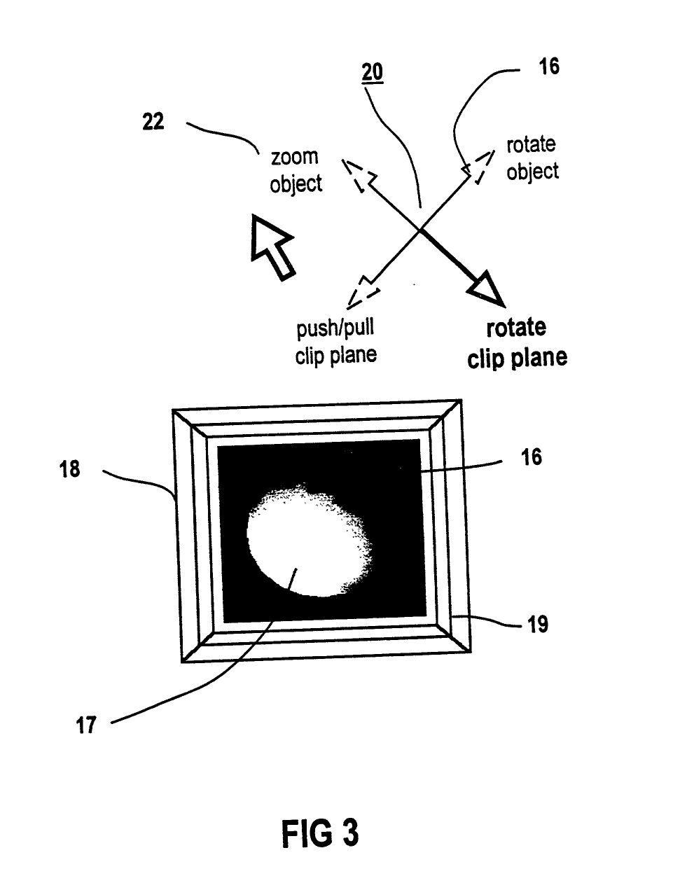

In order to then be able to switch in a simple way from the control function causing rotation of the object to other control functions, a detector 14 is provided which detects short movements with the mouse 13 and executes them in accordance with the direction. The clip plane 19 now can be rotated or displaced, or the object 18 itself can be zoomed. This manner of switching applies to skilled operators. Less skilled operators can right-click the mouse 13 to call up a symbolic context menu 20 which is illustrated in FIG. 3 together with the original object. In this case, arrows 21 specify the direction of movement of the gesture selection, while the lettering 22 of the arrows 21 reproduces the selectable control functions. The current control function “rotate clip plane” and its associated arrow 21 are emphasized in this case. This can be performed by a different color or, as illustrated, by a bold display. The skilled operator can now memorize the control functions and close the menu 20 and carry out the changeover by the short movement with the mouse 13.

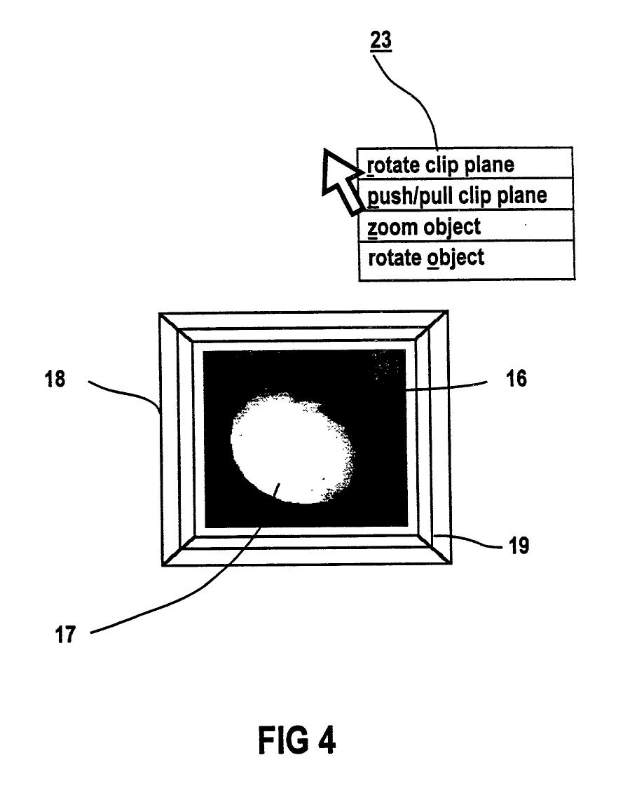

Unskilled operators can briefly right-click the mouse 13 to call up a classic text menu 23 illustrated in FIG. 4, in which there are the control commands which are selected in a known way by inputting the underlined letters.

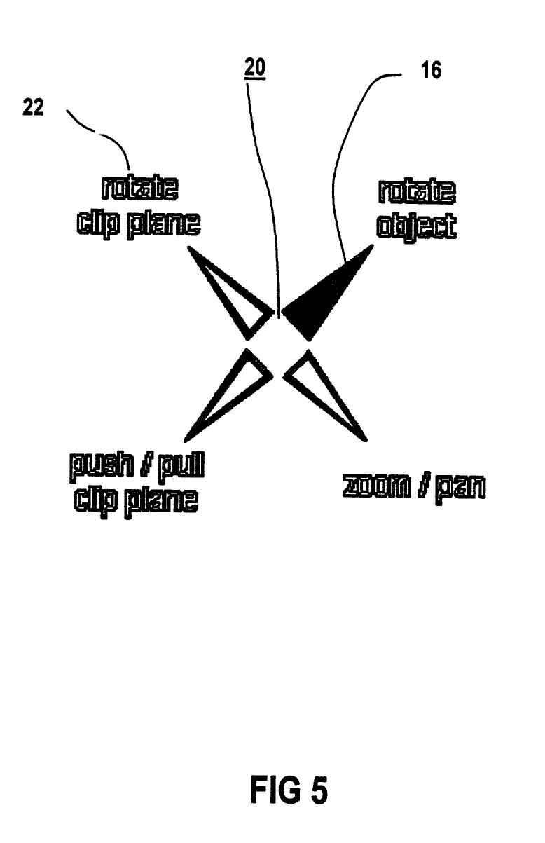

A further embodiment of the symbolic context menu 20 according to the invention is illustrated in FIG. 5, which also has arrows 21 and lettering 22 with the control commands.

In summary, the mouse 13 is left-clicked in order to be able to rotate the volume illustrated in FIG. 2. The mouse is right-clicked in order to be able to rotate the clip plane. The menu illustrated in FIG. 3 appears after a prescribed time of, for example, one second. The arrows 21 and the control commands 22 are marked by moving the mouse 13 into the lower right corner. After the mouse button has been released, it is now possible to rotate the clip plane 19 by left-clicking the mouse 13 and moving the clip plane 19.

The same mechanism can be used to enter the modes of clip plane 19 and zoom object. Of course, it is also possible to return to the volume mode in the same way.

In addition, a normal text menu is provided for the inexperienced user and can be called up by briefly right-clicking the mouse 13 (FIG. 4).

The fast interactive method can be learned easily by means of the menu according to the invention. Novices can use the normal menu, while the experienced operator can use the menu according to the invention together with visual feedback from arrows 21 and control commands 22. Without hesitation and without a need to divert one's field of view from the display screen, skilled operators can effect switching by the appropriate movement with the mouse in the correct direction.

Such switching or changing of the control functions also can be used in the case of two-dimensional (2D) images instead of in 3D visualization. Here, scrolling and zooming as well as tools for selecting ROIs such as, for example, the determination of the contours, can be the control functions that are switched (changed).

Although modifications and changes may be suggested by those skilled in the art, it is the intention of the inventors to embody within the patent warranted hereon all changes and modifications as reasonably and properly come within the scope of their contribution to the art.

We claim as our invention:

1. A diagnostic device comprising:
an arrangement for generating raw data representing an object;
a computer supplied with said raw data for calculating image data from said raw data;
an imaging system connected to said computer and supplied with said image data for generating input signals from said image data;
an input device connected to said imaging system, and having a user-operable mouse;
a display unit connected to said imaging system and supplied with said image signals for displaying an image containing said object dependent on said image signals; and
said imaging system allowing influencing of the display of said image on said display unit by a plurality of control functions entered via said mouse, said input device having a detector which detects a movement of said mouse in one of a plurality of predetermined directions and which selects one of said control functions, dependent on said one of said plurality of predetermined directions, to alter the display of said image on said display unit.

2. A diagnostic device as claimed in claim 1 wherein said arrangement for generating raw data comprises an arrangement for generating raw data representing a volume of said object, and wherein said computer comprises a computer for calculating image data representing a three-dimensional image from said raw data, wherein said imaging system comprises an imaging system for generating image signals from said image data representing a three-dimensional image of said volume, and wherein said display unit displays said three-dimensional image, and wherein said detector alters the display of said three-dimensional image on said display unit dependent on said movement of said mouse in one of said plurality of predetermined directions.

3. A diagnostic device as claimed in claim 2 wherein said control functions are selected from the group consisting of rotating said object in said three-dimensional image, zooming of said object in said three-dimensional image, rotating a clip plane in said three-dimensional image, and displacing a clip plane in said three-dimensional image.

4. A diagnostic device as claimed in claim 1 wherein said detector automatically switches from one of said control functions to another of said control functions upon a brief actuation of said mouse in said one of said plurality of predetermined directions.

5. A diagnostic device as claimed in claim 1 wherein said detector comprises a detector for detecting four defined directions, respectively corresponding to different control functions, by gesture selection.

6. A diagnostic device as claimed in claim 1 wherein said plurality of predetermined directions are respectively oriented at angles of 45° relative to the vertical.

7. A diagnostic device as claimed in claim 1 wherein, upon right-clicking of said mouse, said imaging system causes a text menu to be displayed on said display which symbolizes said plurality of predetermined directions and includes associated text explanations, and wherein said imaging system, controlled by gesture selection using said mouse, automatically changes from one of said control functions to another of said control functions.

8. A diagnostic device as claimed in claim 1 wherein said imaging system, upon briefly right-clicking of said mouse, displays a text menu identifying said plurality of control functions on said display.
